(19) United States
(12) Patent Application Publication
(10) Pub. No.: US 2025/0261462 A1
(43) Pub. Date: Aug. 14, 2025

(54) IMAGE SENSOR WITH INTEGRATED ANTI-REFLECTIVE COATING AND VIA ETCH PROCESS

(71) Applicant: SEMICONDUCTOR COMPONENTS INDUSTRIES, LLC, Scottsdale, AZ (US)

(72) Inventor: Brian Anthony VAARTSTRA, Nampa, ID (US)

(73) Assignee: SEMICONDUCTOR COMPONENTS INDUSTRIES, LLC, Scottsdale, AZ (US)

(21) Appl. No.: 18/436,378

(22) Filed: Feb. 8, 2024

(51) Int. Cl. H01L 27/146

(52) U.S. Cl. CPC H10F 39/805; H10F 39/024; H10F 39/182; H10F 39/8053; H10F 39/8057; H10F 39/8063; H10F 39/809

(57) ABSTRACT

Image sensors and methods for fabricating image sensors. The method includes forming a first photoresist layer on a planarization layer. The method also includes performing a developing process to form a first hole above a bond pad. The method further includes performing a first dry etching process to form a first trench extending toward the bond pad. The method also includes forming an anti-reflective coating (ARC) layer on the planarization layer and along the first trench. The method further includes forming a second photoresist layer on the ARC layer and inside the first trench. The method also includes performing a developing process to form a second hole in extending from the ARC layer of the first trench to the top side of the image sensor. The method further includes performing a second dry etching process to form a second trench from the first trench to the bond pad.

### BACKGROUND

Image sensors are used in electronic devices such as cellular telephones, cameras, and computers to capture images. In particular, an electronic device is provided with an array of image sensor pixels arranged in a grid pattern. Each image sensor pixel receives incident photons, such as light, and converts the photons into electrical signals. Column circuitry is coupled to each column for reading out sensor signals from each image sensor pixel.

### SUMMARY

Bond pads are embedded in image sensor wafers to provide test points or wire connection points. A trench may be formed in an image sensor wafer to permit external connections to an embedded bond pad. Further, an anti-reflective coating that is formed on microlenses of the image sensor may also be formed along the inner border of the trench to protect the silicon (for example, from impurities). Some microelectronic foundries require a pad-open-last process in which a trench for a bond pad is formed in an image sensor wafer after the microlenses are formed. Current pad-open-last processes deposit the anti-reflective coating on the microlenses and along the inner border of bond pad trenches during different processing steps, adding significant expense to the manufacturing of image sensors. Thus, the present disclosure provides methods for fabricating image sensors that deposit an anti-reflective coating on the microlenses and along the inner border of bond pad trenches during the same processing step.

The present disclosure provides a method for fabricating an image sensor. The image sensor includes, in one implementation, photosensitive elements and a planarization layer. The photosensitive elements are a semiconductor substrate. The planarization layer is formed on the semiconductor substrate. The method includes forming a first photoresist layer on the planarization layer. The method also includes performing a first developing process to form a first hole in the first photoresist layer above a bond pad of the image sensor. The method further includes performing a first dry etching process to form a first trench extending toward the bond pad from a top side of the image sensor. The method also includes forming an anti-reflective coating (ARC) layer on the planarization layer and along an inner border of the first trench. The method further includes forming a second photoresist layer on the ARC layer and inside the first trench. The method also includes performing a second developing process to form a second hole in the second photoresist layer extending from the ARC layer at a bottom side of the first trench to the top side of the image sensor. The method further includes performing a second dry etching process to form a second trench from the bottom side of the first trench to the bond pad.

The present disclosure also provides another method for fabricating an image sensor. The image sensor includes, in one implementation, photosensitive elements and a planarization layer. The photosensitive elements are a semiconductor substrate. The planarization layer is formed on the semiconductor substrate. The method includes forming a first photoresist layer on the planarization layer defining a first hole above a bond pad of the image sensor. The method also includes performing a first dry etching process to form a first trench extending toward the bond pad from a top side of the image sensor. The method further includes forming an ARC layer on the planarization layer and along an inner border of the first trench. The method also includes forming a second photoresist layer within the first trench and extending outward from an open end of the first trench. The method further includes forming a third photoresist layer on the ARC layer and the second photoresist layer defining a second hole extending from the ARC layer at a bottom side of the first trench to the top side of the image sensor. The method also includes performing a second dry etching process to form a second trench from the bottom side of the first trench to the bond pad.

The present disclosure further provides an image sensor including, in one implementation, a semiconductor substrate, photosensitive elements, a first dielectric layer, a second dielectric layer, a bond pad, a planarization layer, a trench, and an ARC layer. The photosensitive elements form an array of image sensor pixels in the semiconductor substrate. The first dielectric layer is bonded to a first side of the semiconductor substrate. The second dielectric layer is bonded to a second side of the semiconductor substrate. The bond pad is embedded in the second dielectric layer. The planarization layer is formed on the first dielectric layer and overlaps at least the photosensitive elements and the bond pad. The trench exposes the bond pad through the first dielectric layer, the semiconductor substrate, the second dielectric layer, and the planarization layer. The ARC layer is formed on the planarization layer and along an inner border of the trench. A thickness of the ARC layer covering the planarization layer is the same as the thickness of the ARC layer along the inner border of the trench.

### BRIEF DESCRIPTION OF THE DRAWINGS

For a detailed description of example implementations, reference will now be made to the accompanying drawings in which:

FIG. 1A is a block diagram of an example of an imaging system in accordance with some implementations;

FIG. 1B is a diagram of an example of an imaging system incorporated in a vehicle in accordance with some implementations;

FIG. 2 is a partial schematic and a partial block diagram of an example of an image sensor in accordance with some implementations;

FIG. 3 is a cross-sectional side view of an example of an image sensor before a pad-open-last process in accordance with some implementations;

FIG. 4 is a cross-sectional side view of an example of a bond pad region of the image sensor of FIG. 3 after a photoresist layer is added on a planarization layer in accordance with some implementations;

FIG. 5 is a cross-sectional side view of the bond pad region after a portion of the photoresist layer of FIG. 4 is developed to form a hole in accordance with some implementations;

FIG. 6 is a cross-sectional side view of the bond pad region after the planarization layer, a semiconductor substrate, and a dielectric layer are etched to form a trench in accordance with some implementations;

FIG. 7 is a cross-sectional side view of the bond pad region after an anti-reflective coating layer is added on the planarization layer and in the trench in accordance with some implementations;

FIG. 8 is a cross-sectional side view of the bond pad region after a photoresist layer is added on the anti-reflective coating layer of FIG. 7 and in the trench in accordance with some implementations;

FIG. 9 is a cross-sectional side view of the bond pad region after a portion of the photoresist layer of FIG. 8 is developed to form a hole in accordance with some implementations;

FIG. 10 is a cross-sectional side view of the bond pad region after the anti-reflective coating layer and the dielectric layer are etched to form a trench in accordance with some implementations;

FIG. 11 is a flow diagram of an example of a method for fabricating an image sensor using a pad-open-last process with two photoresist formations in accordance with some implementations;

FIG. 12 is a cross-sectional side view of the bond pad region after the photoresist layer of FIG. 8 is developed to remove portions of the photoresist layer that are not positioned above the bond pad in accordance with some implementations;

FIG. 13 is a cross-sectional side view of the bond pad region after another photoresist layer is added on the photoresist layer of FIG. 12 and the anti-reflective coating layer in accordance with some implementations;

FIG. 14 is a cross-sectional side view of the bond pad region after the photoresist layers of FIGS. 12 and 13 are developed to form a hole in accordance with some implementations;

FIG. 15 is a cross-sectional side view of the bond pad region after the anti-reflective coating layer and the dielectric layer are etched to form a trench in accordance with some implementations; and

FIG. 16 is a flow diagram of an example of a method for fabricating an image sensor using a pad-open-last process with three photoresist formations in accordance with some implementations.

### DEFINITIONS

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or direct connection. Thus, if a first device couples to a second device, that connection may be through a direct connection or through an indirect connection via other devices and connections.

Terms defining an elevation, such as “above,” “below,” “upper”, and “lower” shall be locational terms in reference to a direction of light incident upon a pixel array and/or an image pixel. Light entering shall be considered to interact with or pass objects and/or structures that are “above” and “upper” before interacting with or passing objects and/or structures that are “below” or “lower.” Thus, the locational terms may not have any relationship to the direction of the force of gravity.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate the fact the recited referent may be plural.

In relation to electrical devices, whether stand alone or as part of an integrated circuit, the terms “input” and “output” refer to electrical connections to the electrical devices, and shall not be read as verbs requiring action. For example, a differential amplifier, such as an operational amplifier, may have a first differential input and a second differential input, and these “inputs” define electrical connections to the operational amplifier, and shall not be read to require inputting signals to the operational amplifier.

“Light” or “color” shall mean visible light with wavelengths ranging from about 380 and 700 nanometers (nm). “Light” or “color” shall also mean invisible light, such as infrared light with wavelengths ranging from about 800 nm and 1 millimeter. “Light” or “color” shall also mean invisible light, such as ultraviolet light with wavelengths ranging from about 100 to 400 nm.

“Controller” shall mean, alone or in combination, individual circuit components, an application specific integrated circuit (ASIC), one or more microcontrollers with controlling software, a reduced-instruction-set computer (RISC) with controlling software, a digital signal processor (DSP), one or more processors with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various implementations of the invention. Although one or more of these implementations may be preferred, the implementations disclosed should not be interpreted, or otherwise used, as limiting the scope of the present disclosure, including the claims. In addition, one skilled in the art will understand that the following description has broad application, and the discussion of any implementation is meant only to be exemplary of that implementation, and not intended to intimate that the scope of the present disclosure, including the claims, is limited to that implementation.

Various examples are directed to image sensors and methods for fabricating image sensors. More particularly, at least some examples are directed to image sensors in which an anti-reflective coating is depositing on microlenses (or a planarization layer) over a pixel array and along an inner border of a bond pad during the same processing step. The specification now turns to an example system to orient the reader.

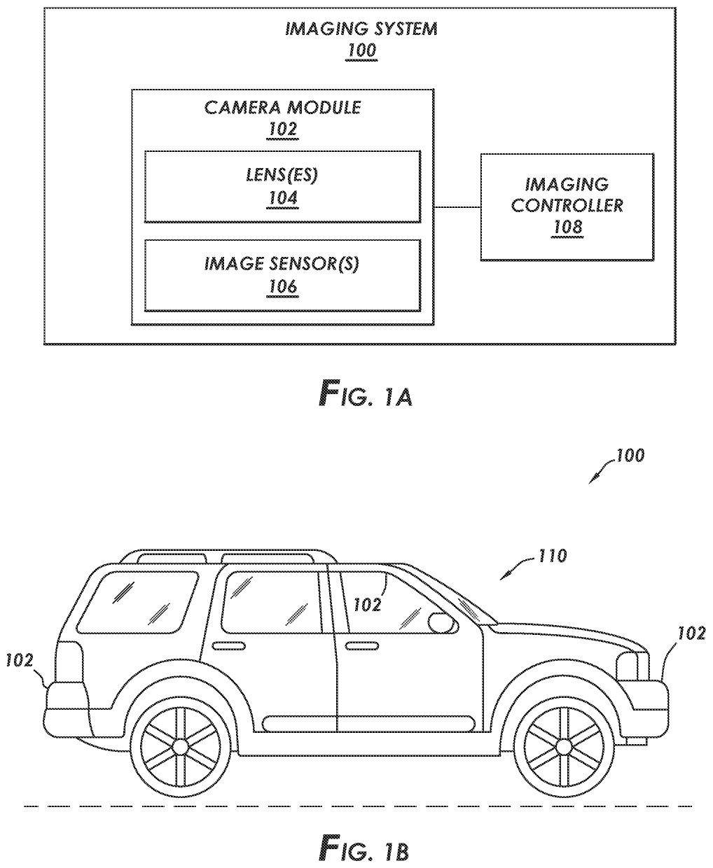

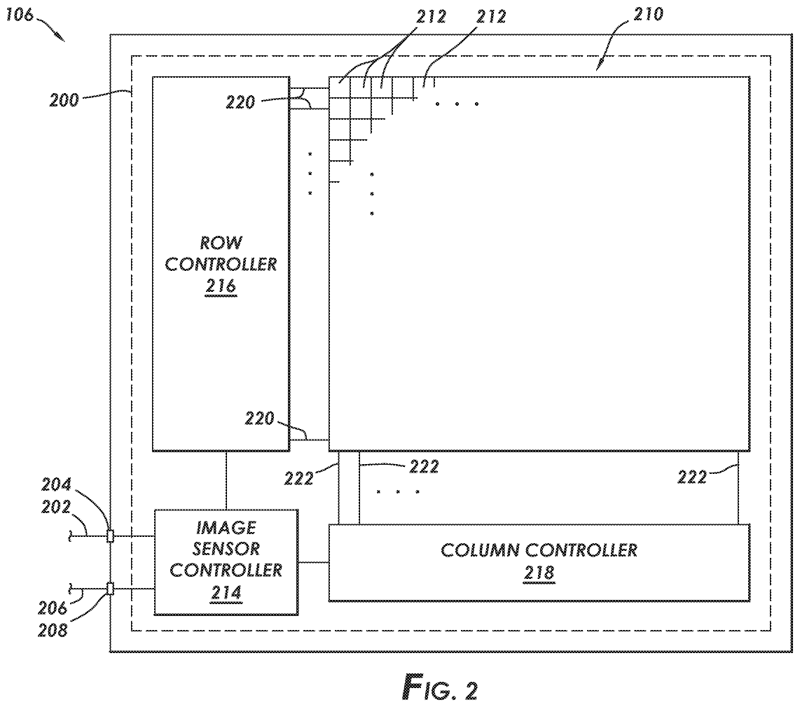

FIG. 1A shows an example of an imaging system 100. In particular, the imaging system 100 may be a portable electronic device such as a camera, a cellular telephone, a tablet computer, a webcam, a video camera, a video surveillance system, or a video gaming system with imaging capabilities. In other cases, the imaging system 100 may be an automotive imaging system. The imaging system 100 illustrated in FIG. 1A includes a camera module 102 that may be used to convert incoming light into digital image data. The camera module 102 may include one or more lenses 104 and one or more corresponding image sensors 106. The lenses 104 may include fixed and/or adjustable lenses. During image capture operations, light from a scene may be focused onto the image sensor 106 by the lenses 104. The image sensor 106 may comprise circuitry for converting analog pixel data into corresponding digital image data to be provided to the imaging controller 108. If desired, the camera module 102 may be provided with an array of lenses 104 and an array of corresponding image sensors 106.

The imaging controller 108 may include one or more integrated circuits. The imaging circuits may include image processing circuits, microprocessors, and storage devices, such as random-access memory, and non-volatile memory. The imaging controller 108 may be implemented using components that are separate from the camera module 102 and/or that form part of the camera module 102, for example, circuits that form part of the image sensor 106. Digital image data captured by the camera module 102 may be processed and stored using the imaging controller 108. Processed image data may, if desired, be provided to external equipment, such as computer, external display, or other device, using wired and/or wireless communications paths coupled to the imaging controller 108.

FIG. 1B shows another example of the imaging system 100. The imaging system 100 illustrated in FIG. 1B comprises an automobile or vehicle 110. The vehicle 110 is illustratively shown as a passenger vehicle, but the imaging system 100 may be other types of vehicles, including commercial vehicles, on-road vehicles, and off-road vehicles. Commercial vehicles may include busses and tractor-trailer vehicles. Off-road vehicles may include tractors and crop harvesting equipment. In the example of FIG. 1B, the vehicle 110 includes a forward-looking cameral module 102 arranged to capture images of scenes in front of the vehicle 110. Such a forward-looking camera module 102 can be used for any suitable purpose, such as lane-keeping assist, collision warning systems, distance-pacing cruise-control systems, autonomous driving systems, and proximity detection. The vehicle 110 further comprises a backward-looking camera module 102 arranged to capture images of scenes behind the vehicle 110. Such a backward-looking camera module 102 can be used for any suitable purpose, such as collision warning systems, reverse direction video, autonomous driving systems, proximity detection, monitoring position of overtaking vehicles, and backing up. The vehicle 110 further comprises a side-looking camera module 102 arranged to capture images of scenes beside the vehicle 110. Such a side-looking camera module 102 can be used for any suitable purpose, such as blind-spot monitoring, collision warning systems, autonomous driving systems, monitoring position of overtaking vehicles, lane-change detection, and proximity detection. In situations in which the imaging system 100 is a vehicle, the imaging controller 108 may be a controller of the vehicle 110. The discussion now turns in greater detail to the image sensor 106 of the camera module 102.

FIG. 2 shows an example of the image sensor 106. In particular, FIG. 2 shows that the image sensor 106 may comprise a substrate 200 of semiconductor material (for example, silicon) encapsulated within packaging to create a packaged semiconductor device or packaged semiconductor product. Bond pads or other connection points of the substrate 200 couple to terminals of the image sensor 106, such as a serial communication channel 202 coupled to a first terminal 204, and a capture input 206 coupled to a second terminal 208. Additional terminals will be present, such as ground, common, or power, but the additional terminals are omitted so as not to unduly complicate the figure. While a single instance of the substrate 200 is shown, in other implementations, multiple substrates may be combined to form the image sensor 106 in a multi-chip module.

The image sensor 106 illustrated in FIG. 2 includes a pixel array 210 with a plurality of image sensor pixels 212 arranged in rows and columns. The pixel array 210, being one example of an “array of pixels,” may include, for example, hundreds or thousands of rows and columns of image sensor pixels 212. Control and readout of the pixel array 210 may be implemented by an image sensor controller 214 coupled to a row controller 216 and a column controller 218. The row controller 216 may receive row addresses from the image sensor controller 214 and supply corresponding row control signals to image sensor pixels 212, such as reset, row-select, charge transfer, dual conversion gain, and readout control signals. The row control signals may be communicated over one or more conductors, such as row control paths 220.

The column controller 218 may be coupled to the pixel array 210 by way of one or more conductors, such as column lines 222. Column controllers may sometimes be referred to as column control circuits, readout circuit, or column decoders. The column lines 222 may be used for reading out pixel signals from image sensor pixels 212 and for supplying bias currents and/or bias voltages to image sensor pixels 212. If desired, during pixel readout operations, a pixel row in the pixel array 210 may be selected using the row controller 216 and pixel signals generated by image sensor pixels 212 in that pixel row can be read out along the column lines 222. The column controller 218 may include sample-and-hold circuitry for sampling and temporarily storing pixel signals read out from the pixel array 210, amplifier circuitry, analog-to-digital conversion (ADC) circuitry, bias circuitry, column memory, latch circuitry for selectively enabling or disabling the column circuitry, or other circuitry that is coupled to one or more columns of image sensor pixels 212 in the pixel array 210 for operating the image sensor pixels 212 and for reading out pixel signals from image sensor pixels 212. ADC circuitry in the column controller 218 may convert analog pixel values received from the pixel array 210 into corresponding digital image data. The column controller 218 may supply digital image data to the image sensor controller 214 and/or the imaging controller 108 (FIG. 1A) over, for example, the serial communication channel 202.

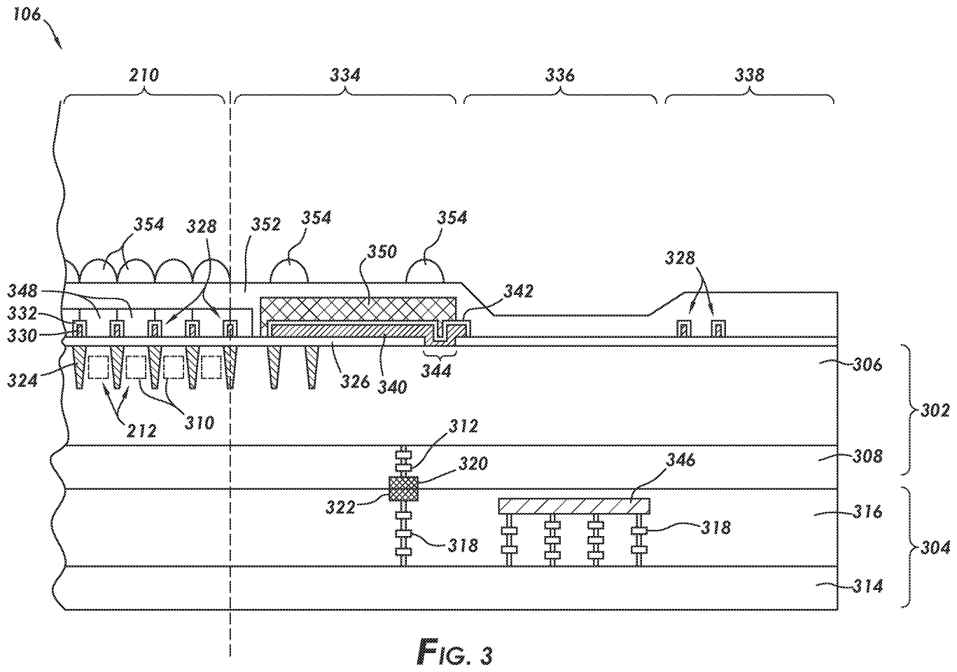

FIG. 3 is a cross-sectional side view of an example of the image sensor 106 during a manufacturing process. The image sensor 106 illustrated in FIG. 3 includes a first chip 302 and a second chip 304. Each chip may sometimes be referred to as a wafer or die. The first chip 302 may sometimes be referred to as a sensor chip whereas the second chip 304 may sometimes be referred to as an application-specific integrated circuit (ASIC) chip. The first chip 302 illustrated in FIG. 3 includes a first semiconductor substrate 306 and a first dielectric layer 308. The first semiconductor substrate 306 (sometimes referred to as semiconductor layer, a silicon layer, or a sensor substrate) may include photosensitive elements 310 for image sensor pixels 212 in the pixel array 210. The first dielectric layer 308 may include various metal layers 312 for forming electrical connections within the first chip 302.

The second chip 304 illustrated in FIG. 3 includes a second semiconductor substrate 314 and a second dielectric layer 316. The second semiconductor substrate 314 (sometimes referred to as a semiconductor layer, a silicon layer, or an ASIC substrate) may include circuitry such as from the image sensor controller 214, the row controller 216, the column controller 218, or a combination thereof. The second dielectric layer 316 may include various metal layers 318 for forming electrical connections within the second chip 304.

As shown in FIG. 3, there may be one or more bonds (sometimes referred to as hybrid bonds) between the first chip 302 and the second chip 304. In FIG. 3, the hybrid bond between the first chip 302 and the second chip 304 is formed by a first conductive layer 320 in the first chip 302 and a second conductive layer 322 in the second chip 304. There may be any desired number of hybrid bonds connecting the first chip 302 to the second chip 304.

The image sensor pixels 212 of the pixel array 210 are distributed across an active area. The image sensor pixels 212 in the pixel array 210 are configured to sense incident light during operation of the image sensor 106. Each image sensor pixel 212 may include a respective photosensitive element 310 (such as a photodiode). Each photosensitive element 310 may be surrounded by a ring of deep trench isolation (DTI) 324. The DTI 324 may be formed by a filler material (for example, a metal filler or low-index filler) in a trench in the first semiconductor substrate 306. The filler material may be partially inside the DTI 324 or extend along the entire depth of the DTI 324. Although the DTI 324 is shown as partially in the first semiconductor substrate 306, it may extend through the entire depth of the first semiconductor substrate 306. The DTI 324 in FIG. 3 is shown as being formed from the backside of the image sensor 106, but it may instead be formed from the front side of the image sensor 106.

A third dielectric layer 326 may be formed over the first semiconductor substrate 306. The third dielectric layer 326 may include, for example, a layer of aluminum oxide (Al₂O₃) on top of the first semiconductor substrate 306, a layer of hafnium oxide (HfO₂) on top of the layer of aluminum oxide, a layer of tantalum oxide (Ta₂O₅) on top of the layer of hafnium oxide, and a layer of silicon dioxide (SiO₂) on top of the layer of tantalum oxide. As shown in FIG. 3, the third dielectric layer 326 may be formed as blanket layers across the entire image sensor 106. In addition to being formed on an upper surface of the first semiconductor substrate 306 as depicted in FIG. 3, the third dielectric layer 326 may be formed within the DTI 324.

The image sensor 106 may include grid structures 328 on top of the third dielectric layer 326. Each grid structure 328 may include a third conductive layer 330 that forms a ring around the footprint of each image sensor pixel 212. The third conductive layer 330 may include, for example, a layer of conductive material (for example, tungsten) and an adhesion layer (for example, a titanium nitride layer). The grid structures 328 may also include a fourth dielectric layer 332 that surrounds the third conductive layers 330. The fourth dielectric layer 332 may be formed, for example, from silicon dioxide.

As shown in FIG. 3, the image sensor 106 includes a peripheral region 334, a bond pad region 336, and a scribe region 338. The peripheral region 334 includes a light shielding layer 340, such as a conductive light shield. The light shielding layer 340 may be substantially opaque to incident light. In some implementations, the light shielding layer 340 may be formed from the same materials as the third conductive layer 330 for the grid structures 328. In other words, the light shielding layer 340 may also be formed from a layer of tungsten over a layer of titanium nitride. Similar to how the grid structures 328 include the fourth dielectric layer 332 over the third conductive layer 330, there may be a fifth dielectric layer 342 over the light shielding layer 340. The fifth dielectric layer 342 may be formed from the same material as the fourth dielectric layer 332 (for example, silicon dioxide). The light shielding layer 340 may overlap one or more of the photosensitive elements 310 in the peripheral region 334. The shielding of the one or more of the photosensitive elements 310 under the light shielding layer 340 are used to provide optically black pixels (which may be used, for example, for noise correction during operation of the image sensor 106).

As shown in FIG. 3, there may be an opening etched in the third dielectric layer 326 to allow a portion of the light shielding layer 340 to be electrically connected to the first semiconductor substrate 306, thereby forming a ground contact 344. Specifically, the light shielding layer 340 may be electrically connected to a deep implant region of the first semiconductor substrate 306 at the ground contact 344. The grid structures 328 may be electrically connected to the light shielding layer 340 such that both the grid structures 328 and the light shielding layer 340 are electrically grounded through the first semiconductor substrate 306 at the ground contact 344.

In the bond pad region 336, the second chip 304 includes a bond pad 346 embedded in the second dielectric layer 316. In the scribe region 338, additional grid structures 328 may be formed (for example, to help with formation of subsequent alignment marks).

Returning to the pixel array 210, color filter elements 348 are formed over each of the image sensor pixels 212. Each of the color filter elements 348 may pass light of any desired color (for example, red, blue, green, yellow, cyan, etc.). In some cases, the image sensor 106 may be a monochrome image sensor and each of the color filter elements 348 may be a clear or gray color filter element.

An opaque layer 350 (sometimes referred to as an opaque dielectric layer, a black layer, or a black dielectric layer) may be formed over the light shielding layer 340 in the peripheral region 334. The opaque layer 350 may conform to the light shielding layer 340 (or the fifth dielectric layer 342). The opaque layer 350 directly contacts an upper surface of the third dielectric layer 326 and the fifth dielectric layer 342 as illustrated in FIG. 3. The opaque layer 350 may have a reflectance of visible light, infrared light, and/or other wavelengths of interest of less than 20%, less than 10%, less than 5%, less than 1%, etc. The opaque layer 350 may have an optical density of 2 (OD2) or greater. The opaque layer 350 therefore prevents visible reflections off the light shielding layer 340.

A planarization layer 352 is formed over the image sensor 106. The planarization layer 352 may be formed from any desired dielectric material. The planarization layer 352 may cover (and directly contact) the color filter elements 348 in the pixel array 210. The planarization layer 352 may cover (and directly contact) the opaque layer 350, the third dielectric layer 326, and/or the fifth dielectric layer 342 in the peripheral region 334. The planarization layer 352 may cover (and directly contact) the third dielectric layer 326 in the bond pad region 336. The planarization layer 352 may cover (and directly contact) the grid structures 328 and the third dielectric layer 326 in the scribe region 338. In some implementations, the planarization layer 352 has a thickness of about 350 nanometers.

Microlenses 354 are formed over each of the image sensor pixels 212 in the pixel array 210. In some implementations, the microlenses 354 or a subset of the microlenses 354 can be formed over 2 or more image sensor pixels. Each of the microlenses 354 may overlap a corresponding color filter element 348 and photosensitive element 310. The microlenses 354 are formed on the planar upper surface provided by the planarization layer 352. In some implementations, the microlenses 354 are formed over the opaque layer 350 in the peripheral region 334 as illustrated in FIG. 3.

As illustrated in FIG. 3, the bond pad 346 is embedded in the second dielectric layer 316. A trench is needed in the image sensor 106 to permit external connections to the bond pad 346. Forming a trench for the bond pad 346 after the microlenses 354 are formed is sometimes referred to as a pad-open-last process. In addition to forming a trench for the bond pad 346, pad-open-last processes form an anti-reflective coating (ARC) over the microlenses 354, the planarization layer 352, and along the inner border of the trench of the bond pad 346. The ARC formed over the microlenses 354 and the planarization layer 352 prevents light reflection whereas the ARC formed along the inner border of the trench for the bond pad 346 protects and passivates the silicon in the first semiconductor substrate 306.

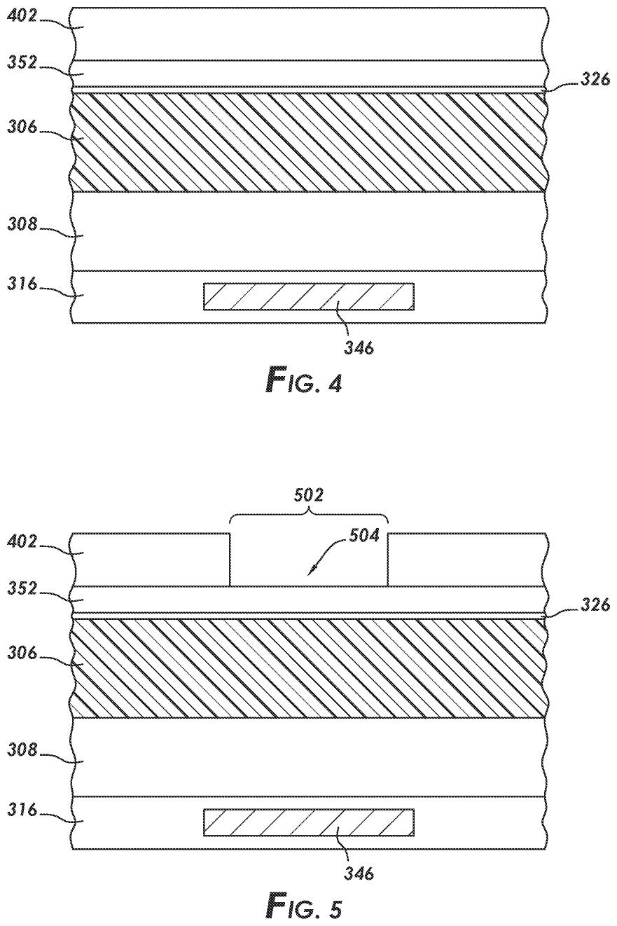

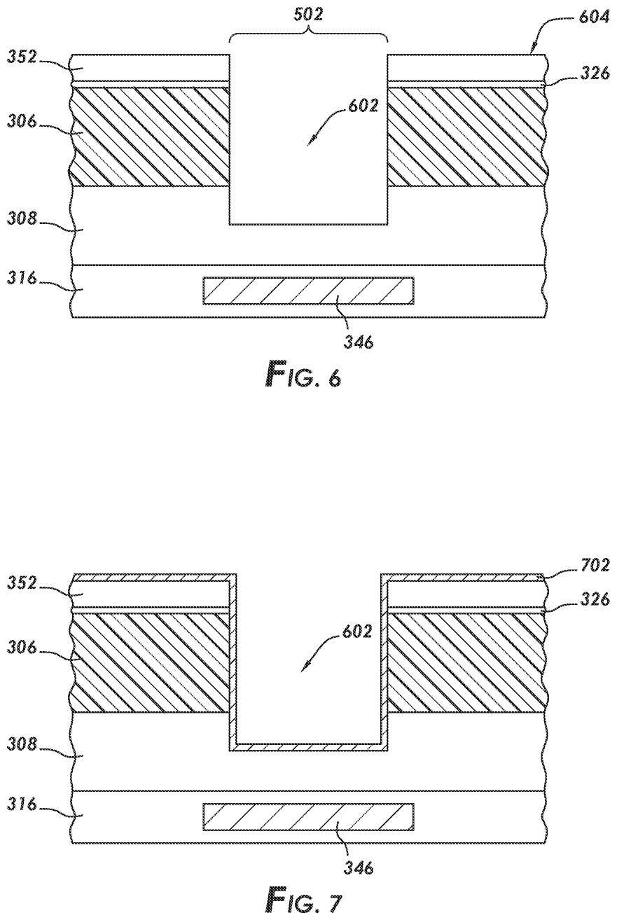

FIGS. 4-10 are cross-sectional side views of the bond pad region 336 during different steps of an example of a pad-open-last in which an ARC is deposited on the planarization layer 352 (and the microlenses 354) and along the inner border of a bond pad trench during the same processing step. The pad-open-last process illustrated in FIGS. 4-10 is performed on the image sensor 106 illustrated in FIG. 3. In FIG. 4, a first photoresist layer 402 is formed over the planarization layer 352. In FIG. 5, the first photoresist layer 402 is developed in region 502 (via a developing process) to form a first hole 504 above the bond pad 346. In FIG. 6, the planarization layer 352, the third dielectric layer 326, the first semiconductor substrate 306, and the first dielectric layer 308 are etched (removed) in region 502. After the etching is complete, there is a first trench 602 extending toward the bond pad 346 from a top side 604 of the image sensor 106. The first trench 602 extends through the planarization layer 352, the third dielectric layer 326, and the first semiconductor substrate 306, and extends partially through the first dielectric layer 308.

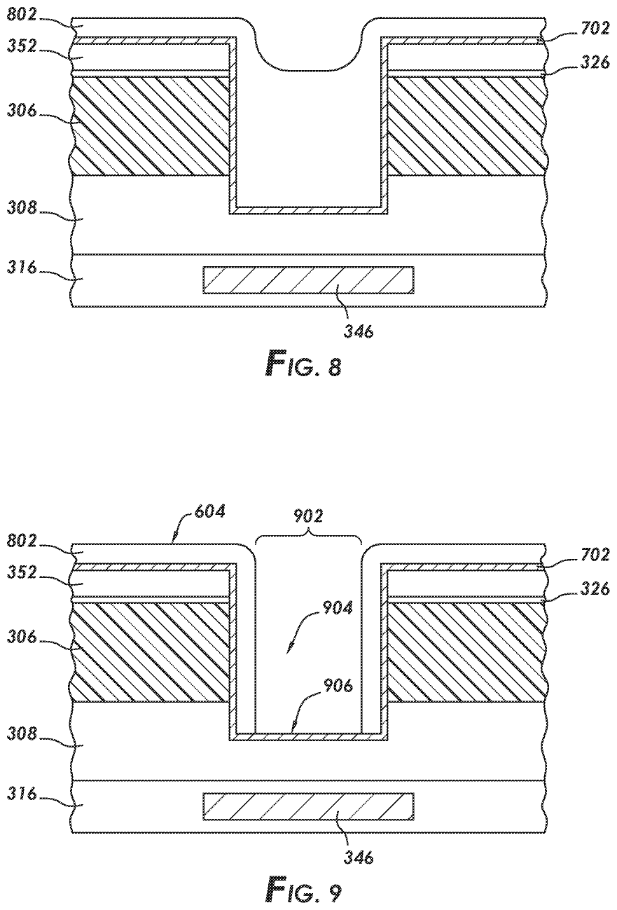

In FIG. 7, an ARC layer 702 (sometimes referred to as an anti-reflective layer, a silicon dioxide layer, or a dielectric layer) is formed to cover the planarization layer 352 and an inner border of the first trench 602. Further, although not visible in the specific field-of-view illustrated in FIG. 7, the ARC layer 702 is also formed on the microlenses 354. In some implementations, the ARC layer 702 is formed from a material with a refractive index that is lower than the refractive index of the material in the planarization layer 352. For example, the ARC layer 702 may be formed from silicon dioxide. The ARC layer 702 has a uniform thickness across the image sensor 106. For example, the thickness of the ARC layer 702 may be uniform within 5% across the image sensor 106. In some implementations, the thickness of the ARC layer 702 is about 100 nanometers.

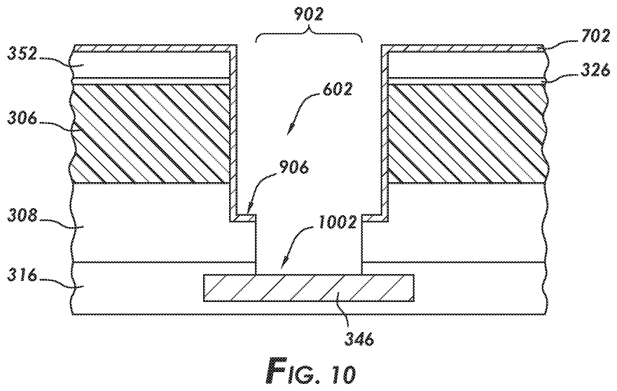

In FIG. 8, a second photoresist layer 802 is formed over the ARC layer 702 and in the first trench 602. In FIG. 9, the second photoresist layer 802 is developed in region 902 (via a developing process) to form a second hole 904 extending from the ARC layer 702 at a bottom side 906 of the first trench 602 to the top side 604 of the image sensor 106. In FIG. 10, the ARC layer 702, the first dielectric layer 308, and the second dielectric layer 316 are etched (removed) in region 902. After the etching is complete, there is a second trench 1002 from the bottom side 906 of the first trench 602 to the bond pad 346. The second trench 1002 extends partially through the first dielectric layer 308 and partially through the second dielectric layer 316.

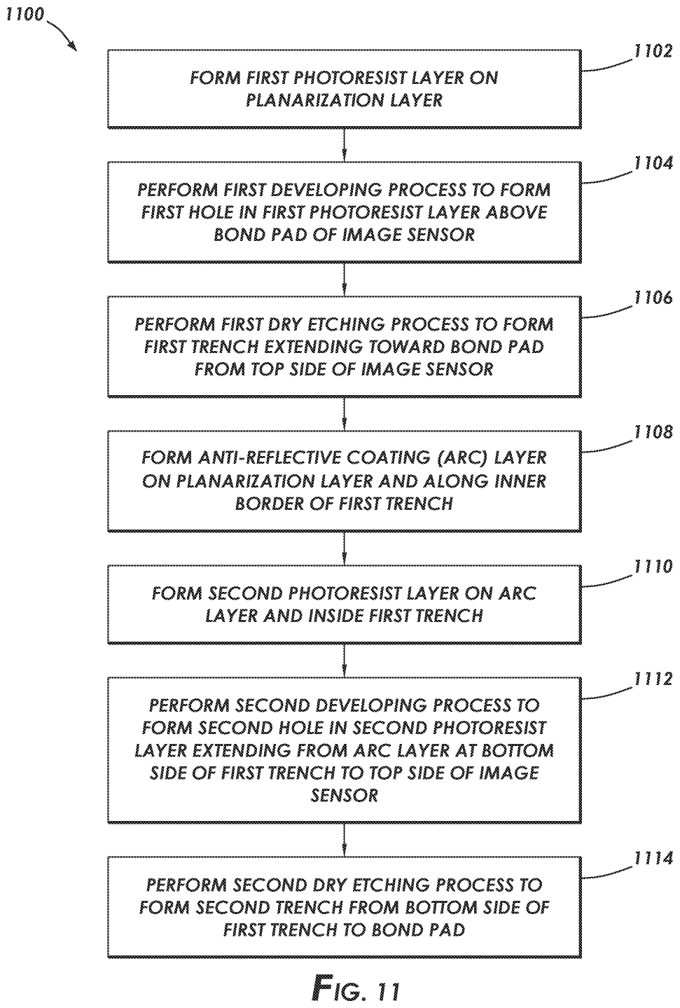

FIG. 11 is a flow diagram of an example of a method 1100 for fabricating an image sensor with a pad-open-last process in accordance with some implementations. For simplicity of explanation, the method 1100 is depicted in FIG. 11 and described as a series of operations. However, the operations can occur in various orders and/or concurrently, and/or with other operations not presented and described herein. At block 1102, a first photoresist layer is formed on a planarization layer. For example, the first photoresist layer 402 may be formed on the planarization layer 352 as illustrated in FIG. 4. At block 1104, a first developing process is performed to form a first hole in the first photoresist layer above a bond pad of the image sensor. For example, the first photoresist layer 402 may be developed in region 502 to form the first hole 504 above the bond pad 346 as illustrated in FIG. 5. At block 1106, a first dry etching process is performed to form a first trench extending toward the bond pad from the top side of the image sensor. For example, the planarization layer 352, the third dielectric layer 326, the first semiconductor substrate 306, and the first dielectric layer 308 are etched (removed) in region 502 to form the first trench 602 extending toward the bond pad 346 from a top side 604 of the image sensor 106 as illustrated in FIG. 6. At block 1108, an ARC layer is formed on the planarization layer and along an inner border of the first trench. For example, the ARC layer 702 may be formed to cover the planarization layer 352 and the inner border of the first trench 602 as illustrated in FIG. 7. At block 1110, a second photoresist layer is formed on the ARC layer and inside the first trench. For example, the second photoresist layer 802 may be formed over the ARC layer 702 and inside the first trench 602 as illustrated in FIG. 8. At block 1112, a second developing process is performed to form a second hole in the second photoresist layer extending from the ARC layer at a bottom side of the first trench to the top side of the image sensor. For example, the second photoresist layer 802 may be developed in region 902 to form the second hole 904 extending from the ARC layer 702 at the bottom side 906 of the first trench 602 to the top side 604 of the image sensor 106 as illustrated in FIG. 9. At block 1114, a second dry etching process is performed to form a second trench from the bottom side of the first trench to the bond pad. For example, the ARC layer 702, the first dielectric layer 308, and the second dielectric layer 316 may be etched (removed) in region 902 to form the second trench 1002 from the bottom side 906 of the first trench 602 to the bond pad 346 as illustrated in FIG. 10.

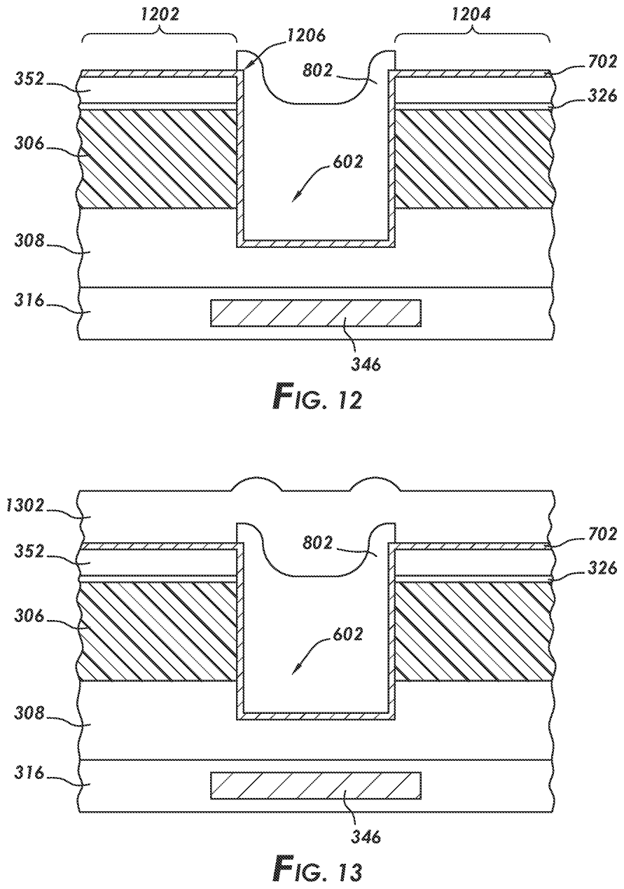

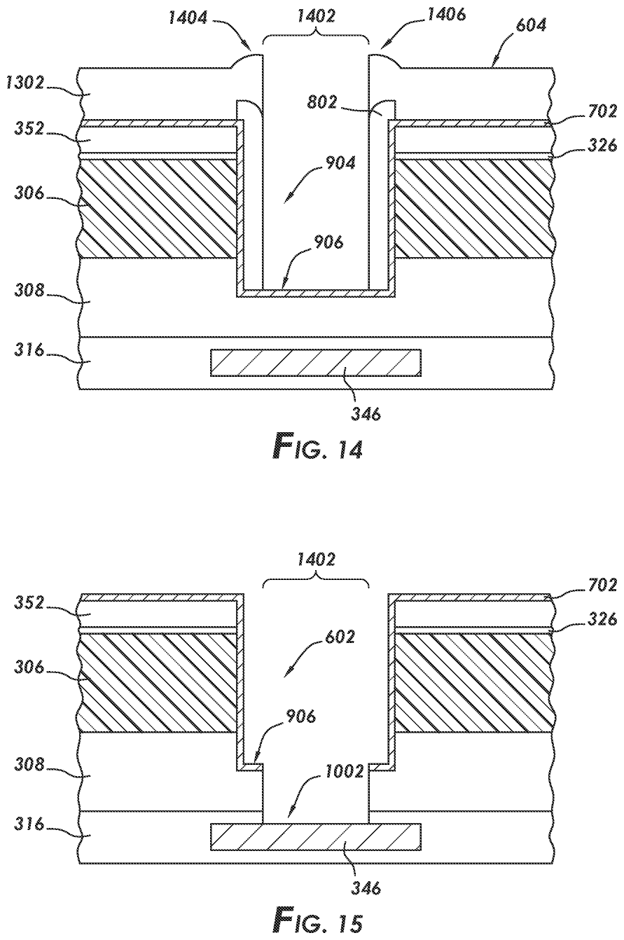

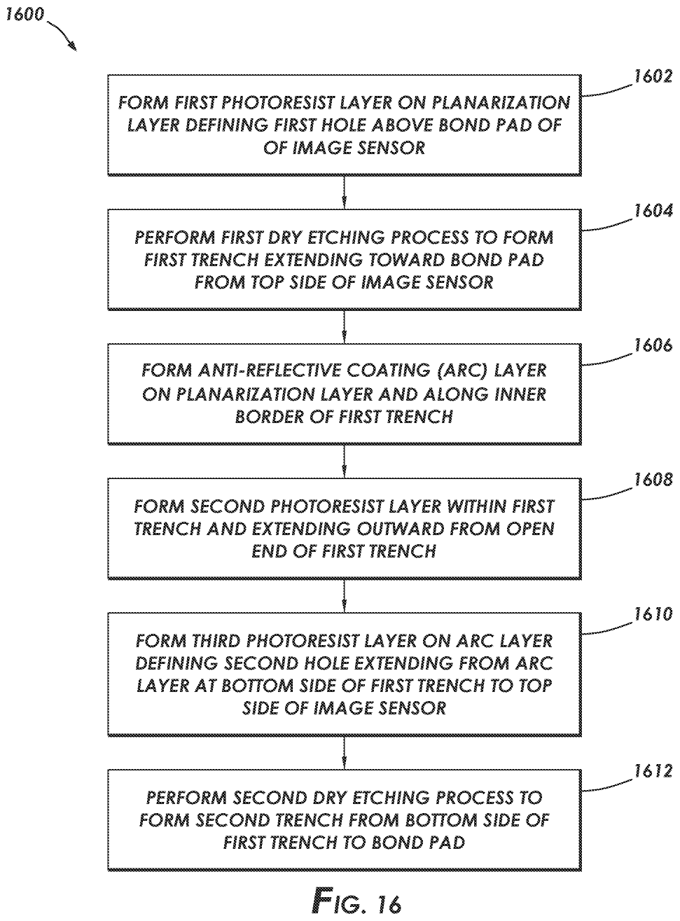

In some implementations, multiple photoresists are formed to generate the second trench 1002. For example, FIGS. 12-15 are cross-sectional side views of the bond pad region 336 during different steps of a portion of a pad-open-last process in which two photoresist layers are formed to generate the second trench 1002. The portion of the pad-open-last process illustrated in FIGS. 12-15 is performed on the image sensor 106 after the second photoresist layer 802 is formed as illustrated in FIG. 8. In FIG. 12, the second photoresist layer 802 is developed in regions 1202 and 1204 (via a developing process) to remove portions of the second photoresist layer 802 that are not positioned above the first trench 602. In addition, the second photoresist layer 802 may be developed such that the portion remaining after the developing process extends outward from the open end of the first trench 602. For example, the second photoresist layer 802 may extend beyond an outer boundary 1206 of the open end of the first trench 602 as illustrated in FIG. 12. In FIG. 13, a third photoresist layer 1302 is formed over the ARC layer 702 and the second photoresist layer 802. In FIG. 14, the second photoresist layer 802 and the third photoresist layer 1302 are developed in region 1402 (via a developing process) to form the second hole 904 from the ARC layer 702 at the bottom side 906 of the first trench 602 to the top side 604 of the image sensor 106. As illustrated in FIG. 14, the third photoresist layer 1302 includes bulges 1404 and 1406 that protect the corner of the first semiconductor substrate 306 during the etching process. In addition, the bulges 1404 and 1406 improve the uniformity of the third photoresist layer 1302 when the second hole 904 is filled. In FIG. 15, the ARC layer 702, the first dielectric layer 308, and the second dielectric layer 316 are etched (removed) in region 1402. After the etching is complete, there is the second trench 1002 from the bottom side 906 of the first trench 602 to the bond pad 346. The second trench 1002 extends partially through the first dielectric layer 308 and partially through the second dielectric layer 316.

FIG. 16 is a flow diagram of an example of a method 1600 for fabricating an image sensor with a pad-open-last process using three photoresist formations in accordance with some implementations. For simplicity of explanation, the method 1600 is depicted in FIG. 16 and described as a series of operations. However, the operations can occur in various orders and/or concurrently, and/or with other operations not presented and described herein. At block 1602, a first photoresist layer is formed on the planarization layer defining a first hole above a bond pad of the image sensor. For example, the first photoresist layer 402 may be formed on the planarization layer 352 such that the first hole 504 is defined above the bond pad 346 as illustrated in FIG. 5. At block 1604, a first dry etching process is performed to form a first trench extending toward the bond pad from a top side of the image sensor. For example, the planarization layer 352, the third dielectric layer 326, the first semiconductor substrate 306, and the first dielectric layer 308 are etched (removed) in region 502 to form the first trench 602 extending toward the bond pad 346 from the top side 604 of the image sensor 106 as illustrated in FIG. 6. At block 1606, an ARC layer is formed on the planarization layer and along an inner border of the first trench. For example, the ARC layer 702 may be formed to cover the planarization layer 352 and along the inner border of the first trench 602 as illustrated in FIG. 7. At block 1608, a second photoresist layer is formed within the first trench and extending outward from an open end of the first trench. For example, the second photoresist layer 802 may be formed within the first trench 602 and extending outward from the open end of the first trench 602 as illustrated in FIG. 12. At block 1610, a third photoresist layer is formed on the ARC layer and the second photoresist layer defining a second hole extending from the ARC layer at a bottom of the first trench to the top side of the image sensor. For example, the third photoresist layer 1302 may be formed on the ARC layer 702 and the second photoresist layer 802 as illustrated in FIG. 14. Further, the third photoresist layer 1302 may define the second hole 904 that extends from the ARC layer 702 at the bottom side 906 of the first trench 602 to the top side 604 of the image sensor 106 as also illustrated in FIG. 14. At block 1612, a second dry etching process is performed to form a second trench from the bottom of the first trench to the bond pad. For example, the ARC layer 702, the first dielectric layer 308, and the second dielectric layer 316 may be etched (removed) in region 1402 to form the second trench 1002 from the bottom side 906 of the first trench 602 to the bond pad 346 as illustrated in FIG. 15.

Consistent with the above disclosure, the examples of systems and methods enumerated in the following clauses are specifically contemplated and are intended as a non-limiting set of examples.

Clause 1. A method for fabricating an image sensor with photosensitive elements in a semiconductor substrate and a planarization layer formed on the semiconductor substrate, the method comprising:
forming a first photoresist layer on the planarization layer;
performing a first developing process to form a first hole in the first photoresist layer above a bond pad of the image sensor;
performing a first dry etching process to form a first trench extending toward the bond pad from a top side of the image sensor;
forming an anti-reflective coating (ARC) layer on the planarization layer and along an inner border of the first trench;
forming a second photoresist layer on the ARC layer and inside the first trench;
performing a second developing process to form a second hole in the second photoresist layer extending from the ARC layer at a bottom side of the first trench to the top side of the image sensor; and
performing a second dry etching process to form a second trench from the bottom side of the first trench to the bond pad.

Clause 2. The method of any clause herein, wherein a thickness of the ARC layer covering the planarization layer is the same as the thickness of the ARC layer along the inner border of the first trench.

Clause 3. The method of any clause herein, wherein the thickness of the ARC layer is about 100 nanometers.

Clause 4. The method of any clause herein, wherein a refractive index of the ARC layer is lower than a refractive index of the planarization layer.

Clause 5. The method of any clause herein, further comprising:
forming color filter elements that overlap the photosensitive elements; and
forming the planarization layer to overlap the color filter elements.

Clause 6. The method of any clause herein, further comprising forming a plurality of microlenses on the planarization layer, wherein the plurality of microlenses overlap the color filter elements, wherein forming the ARC layer on the planarization layer further includes forming the ARC layer on the plurality of microlenses.

Clause 7. A method for fabricating an image sensor with photosensitive elements in a semiconductor substrate and a planarization layer formed on the semiconductor substrate, the method comprising:
forming a first photoresist layer on the planarization layer defining a first hole above a bond pad of the image sensor;
performing a first dry etching process to form a first trench extending toward the bond pad from a top side of the image sensor;
forming an anti-reflective coating (ARC) layer on the planarization layer and along an inner border of the first trench;
forming a second photoresist layer within the first trench and extending outward from an open end of the first trench;
forming a third photoresist layer on the ARC layer and the second photoresist layer defining a second hole extending from the ARC layer at a bottom side of the first trench to the top side of the image sensor; and
performing a second dry etching process to form a second trench from the bottom side of the first trench to the bond pad.

Clause 8. The method of any clause herein, wherein the second photoresist layer is further formed such that the second photoresist layer extends beyond an outer boundary of the open end of the first trench.

Clause 9. The method of any clause herein, wherein the ARC layer comprises silicon dioxide.

Clause 10. The method of any clause herein, wherein a thickness of the ARC layer is about 100 nanometers.

Clause 11. The method of any clause herein, further comprising:
forming color filter elements that overlap the photosensitive elements; and
forming the planarization layer to overlap the color filter elements.

Clause 12. The method of any clause herein, further comprising forming a plurality of microlenses on the planarization layer, wherein the plurality of microlenses overlap the color filter elements, wherein forming the ARC layer on the planarization layer further includes forming the ARC layer on the plurality of microlenses.

Clause 13. The method of any clause herein, wherein forming the first photoresist layer on the planarization layer further comprises performing a first developing process to remove a portion of the first photoresist layer positioned above the bond pad to form the first hole.

Clause 14. An image sensor, comprising:
a semiconductor substrate;
photosensitive elements forming an array of image sensor pixels in the semiconductor substrate;
a first dielectric layer bonded to a first side of the semiconductor substrate;
a second dielectric layer bonded to a second side of the semiconductor substrate;
a bond pad embedded in the second dielectric layer;
a planarization layer formed on the first dielectric layer and overlapping at least the photosensitive elements and the bond pad;
a trench exposing the bond pad through the first dielectric layer, the semiconductor substrate, the second dielectric layer, and the planarization layer; and
an anti-reflective coating (ARC) layer formed on the planarization layer and along an inner border of the trench,
wherein a thickness of the ARC layer covering the planarization layer is the same as the thickness of the ARC layer along the inner border of the trench.

Clause 15. The image sensor of any clause herein, further comprising:
at least one additional photosensitive element in the semiconductor substrate outside of the array of image sensor pixels;
a conductive light shield that overlaps the at least one additional photosensitive element; and
an opaque layer that overlaps the conductive light shield,
wherein the planarization layer further overlaps the opaque layer.

Clause 16. The image sensor of any clause herein, wherein the thickness of the ARC layer is about 100 nanometers.

Clause 17. The image sensor of any clause herein, wherein a refractive index of the ARC layer is lower than a refractive index of the planarization layer.

Clause 18. The image sensor of any clause herein, further comprising color filter elements that overlap the photosensitive elements.

Clause 19. The image sensor of any clause herein, further comprising a plurality of microlenses that overlap the color filter elements, wherein the ARC layer is further formed on the plurality of microlenses.

Clause 20. The image sensor of any clause herein, wherein the thickness of the planarization layer is about 350 nanometers.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s).

The above discussion is meant to be illustrative of the principles and various implementations of the present invention. Numerous variations and modifications will become apparent to those skilled in the art once the above disclosure is fully appreciated. It is intended that the following claims be interpreted to embrace all such variations and modifications.

What is claimed is:

1. A method for fabricating an image sensor with photosensitive elements in a semiconductor substrate and a planarization layer formed on the semiconductor substrate, the method comprising:
forming a first photoresist layer on the planarization layer;
performing a first developing process to form a first hole in the first photoresist layer above a bond pad of the image sensor;
performing a first dry etching process to form a first trench extending toward the bond pad from a top side of the image sensor;
forming an anti-reflective coating (ARC) layer on the planarization layer and along an inner border of the first trench;
forming a second photoresist layer on the ARC layer and inside the first trench;
performing a second developing process to form a second hole in the second photoresist layer extending from the ARC layer at a bottom side of the first trench to the top side of the image sensor; and
performing a second dry etching process to form a second trench from the bottom side of the first trench to the bond pad.

2. The method of claim 1, wherein a thickness of the ARC layer covering the planarization layer is the same as the thickness of the ARC layer along the inner border of the first trench.

3. The method of claim 2, wherein the thickness of the ARC layer is about 100 nanometers.

4. The method of claim 1, wherein a refractive index of the ARC layer is lower than a refractive index of the planarization layer.

5. The method of claim 1, further comprising:
forming color filter elements that overlap the photosensitive elements; and
forming the planarization layer to overlap the color filter elements.

6. The method of claim 5, further comprising forming a plurality of microlenses on the planarization layer, wherein the plurality of microlenses overlap the color filter elements, wherein forming the ARC layer on the planarization layer further includes forming the ARC layer on the plurality of microlenses.

7. A method for fabricating an image sensor with photosensitive elements in a semiconductor substrate and a planarization layer formed on the semiconductor substrate, the method comprising:
forming a first photoresist layer on the planarization layer defining a first hole above a bond pad of the image sensor;
performing a first dry etching process to form a first trench extending toward the bond pad from a top side of the image sensor;
forming an anti-reflective coating (ARC) layer on the planarization layer and along an inner border of the first trench;
forming a second photoresist layer within the first trench and extending outward from an open end of the first trench;
forming a third photoresist layer on the ARC layer and the second photoresist layer defining a second hole extending from the ARC layer at a bottom side of the first trench to the top side of the image sensor; and
performing a second dry etching process to form a second trench from the bottom side of the first trench to the bond pad.

8. The method of claim 7, wherein the second photoresist layer is further formed such that the second photoresist layer extends beyond an outer boundary of the open end of the first trench.

9. The method of claim 7, wherein the ARC layer comprises silicon dioxide.

10. The method of claim 7, wherein a thickness of the ARC layer is about 100 nanometers.

11. The method of claim 7, further comprising:
forming color filter elements that overlap the photosensitive elements; and
forming the planarization layer to overlap the color filter elements.

12. The method of claim 11, further comprising forming a plurality of microlenses on the planarization layer, wherein the plurality of microlenses overlap the color filter elements, wherein forming the ARC layer on the planarization layer further includes forming the ARC layer on the plurality of microlenses.

13. The method of claim 7, wherein forming the first photoresist layer on the planarization layer further comprises performing a first developing process to remove a portion of the first photoresist layer positioned above the bond pad to form the first hole.

14. An image sensor, comprising:
a semiconductor substrate;
photosensitive elements forming an array of image sensor pixels in the semiconductor substrate;
a first dielectric layer bonded to a first side of the semiconductor substrate;
a second dielectric layer bonded to a second side of the semiconductor substrate;
a bond pad embedded in the second dielectric layer;
a planarization layer formed on the first dielectric layer and overlapping at least the photosensitive elements and the bond pad;
a trench exposing the bond pad through the first dielectric layer, the semiconductor substrate, the second dielectric layer, and the planarization layer; and
an anti-reflective coating (ARC) layer formed on the planarization layer and along an inner border of the trench,
wherein a thickness of the ARC layer covering the planarization layer is the same as the thickness of the ARC layer along the inner border of the trench.

15. The image sensor of claim 14, further comprising:
at least one additional photosensitive element in the semiconductor substrate outside of the array of image sensor pixels;
a conductive light shield that overlaps the at least one additional photosensitive element; and
an opaque layer that overlaps the conductive light shield,
wherein the planarization layer further overlaps the opaque layer.

16. The image sensor of claim 14, wherein the thickness of the ARC layer is about 100 nanometers.

17. The image sensor of claim 14, wherein a refractive index of the ARC layer is lower than a refractive index of the planarization layer.

18. The image sensor of claim 14, further comprising color filter elements that overlap the photosensitive elements.

19. The image sensor of claim 18, further comprising a plurality of microlenses that overlap the color filter elements, wherein the ARC layer is further formed on the plurality of microlenses.

20. The image sensor of claim 14, wherein the thickness of the planarization layer is about 350 nanometers.
